(19) United States
(12) Patent Application Publication
(10) Pub. No.: US 2026/0131355 A1
(43) Pub. Date: May 14, 2026

(54) FILM FORMATION METHOD AND FILM FORMATION APPARATUS

(71) Applicant: Tokyo Electron Limited, Tokyo (JP)

(72) Inventors: Yumiko KAWANO, Nirasaki-shi (JP); Shinichi IKE, Hwaseong-si (KR); Shuji AZUMO, Nirasaki-shi (JP)

(21) Appl. No.: 19/430,642

(22) Filed: Dec. 23, 2025

Related U.S. Application Data
(62) Division of application No. 17/757,376.

(30) Foreign Application Priority Data
Dec. 27, 2019 (JP) 2019-239350

(51) Int. Cl. B05D 1/18; B05D 1/00; B05D 1/12; B05D 3/10; C23C 16/04; H10P 14/61

(52) U.S. Cl. CPC B05D 1/185; B05D 1/005; B05D 1/12; B05D 3/107; C23C 16/042; H10P 14/61

(57) ABSTRACT

A film formation method includes: preparing a substrate including, on its surface, a first region in which a first material is exposed and a second region in which a second material different from the first material is exposed; selectively forming a self-assembled monolayer in the first region, among the first region and the second region; and forming a desired target film in the second region, among the first region and the second region, by using the self-assembled monolayer formed in the first region, wherein the selectively forming the self-assembled monolayer includes: selectively forming the self-assembled monolayer in the first region by using a first processing liquid including a first raw material of the self-assembled monolayer; and modifying the self-assembled monolayer, by using a second processing liquid including a second raw material of the self-assembled monolayer at a concentration different from a concentration of the first processing liquid.

### CROSS-REFERENCE TO RELATED APPLICATIONS

The present application is a divisional of U.S. patent application Ser. No. 17/757,736, filed on Jun. 15, 2022, which is a U.S. National Stage Entry of International Patent Application No. PCT/JP 2020/046621, filed Dec. 14, 2020, which claims the benefit of priority to Japanese Patent Application No. 2019-239350, filed Dec. 27, 2019, each of which is hereby incorporated herein by reference in its entirety.

### TECHNICAL FIELD

The present disclosure relates to a film formation method and a film formation apparatus.

### BACKGROUND

Patent Documents 1 to 3 disclose a technique for selectively forming a target film in a specific region of a substrate without using a photolithography technique. Specifically, Patent Documents 1 to 3 disclose a technique for forming a self-assembled monolayer (SAM) that inhibits the formation of a target film in a partial region of the substrate and forming the target film in the remaining region of the substrate.

In Patent Document 1, a first organic precursor and a second organic precursor are supplied to the surface of an integrated circuit structure as raw materials for a SAM. The first organic precursor has a first molecular chain length and the second organic precursor has a second molecular chain length shorter than the first molecular chain length. The integrated circuit structure has a first surface and a second surface that is different from the first surface. The first organic precursor covers a portion of the first surface and the second organic precursor covers the rest of the first surface.

In Patent Document 2, the substrate is immersed in a solution containing a raw material of a SAM and a solvent to form the SAM on the exposed silicon-containing surface. The raw material of a SAM is, for example, organosilane. The silicon-containing surface is, for example, a SiO₂ surface. The SAM suppresses the formation of a low-dielectric constant dielectric layer on the silicon-containing surface. The low-dielectric constant dielectric layer is selectively deposited on the silicon surface (Si surface).

In Patent Document 3, a solution containing a raw material of a SAM and a solvent is applied to a substrate through a spin coating method, and then the substrate surface is dried through a method of rotating the substrate or a method of spraying dry air or nitrogen gas, and a SAM is formed on the substrate surface. The raw material of the SAM is, for example, an alkylsilane compound.

PRIOR ART DOCUMENTS

### Patent Documents

Patent Document 1: Japanese Laid-Open Patent Publication No. 2013-520028

Patent Document 2: Japanese Laid-Open Patent Publication No. 2018-512504

Patent Document 3: Japanese Laid-Open Patent Publication No. 2009-290187

An aspect of the present disclosure provides a technique capable of improving a blocking performance of a SAM.

### SUMMARY

A film formation method of an aspect of the present disclosure includes (A) to (C) below. (A) Preparing a substrate including, on a surface of the substrate, a first region in which a first material is exposed and a second region in which a second material different from the first material is exposed. (B) Selectively forming a self-assembled monolayer in the first region, among the first region and the second region. (C) Forming a desired target film in the second region, among the first region and the second region, by using the self-assembled monolayer formed in the first region. The (B) includes (Ba) and (Bb) below. (Ba) Selectively forming the self-assembled monolayer in the first region by using a first processing liquid including a first raw material of the self-assembled monolayer. (Bb) Modifying the self-assembled monolayer formed by the first processing liquid, by using a second processing liquid including a second raw material of the self-assembled monolayer at a concentration different from a concentration of the first processing liquid.

According to an aspect of the present disclosure, it is possible to improve a blocking performance of a SAM.

### BRIEF DESCRIPTION OF DRAWINGS

FIG. 1 is a flowchart illustrating a film formation method according to an embodiment.

FIG. 2 is a flowchart illustrating an example of S2 of FIG. 1.

FIG. 3A is a side view illustrating an example of a substrate in S1 of FIG. 1.

FIG. 3B is a side view illustrating an example of a substrate in S21 of FIG. 2.

FIG. 3C is a side view illustrating an example of a substrate in S22 of FIG. 2.

FIG. 3D is a side view illustrating an example of a substrate in S24 of FIG. 2.

FIG. 3E is a view illustrating an example of a substrate in S3 of FIG. 1.

FIG. 4 is a plan view illustrating a film formation apparatus according to an embodiment.

FIG. 5 is a cross-sectional view illustrating an example of a first processor of FIG. 4.

FIG. 6 is a cross-sectional view illustrating a modification of the first processor of FIG. 4.

FIG. 7 is a cross-sectional view illustrating an example of a second processor of FIG. 4.

FIG. 8 is an SEM photograph showing a surface state of the substrate immediately after S21 of Example 1.

FIG. 9 is an SEM photograph showing a surface state of the substrate immediately after S22 of Example 1.

FIG. 10 is an SEM photograph showing a surface state of the substrate immediately after S22 of a reference example.

FIG. 11 is a view showing data obtained by measuring surface states of first regions immediately after formation of AlO films with an X-ray photoelectron spectroscopy (XPS) device for Example 1 and Comparative Examples 1 and 2.

FIG. 12 is a view showing data obtained by measuring surface states of the first regions immediately after the formation of AlO films with an X-ray photoelectron spectroscopy (XPS) device for Examples 1 and 2 and Comparative Example 3.

FIG. 13 is a view showing data obtained by measuring surface states of the first regions immediately after the formation of AlO films with an X-ray photoelectron spectroscopy (XPS) device for Example 3 and Comparative Example 4.

FIG. 14 is a view showing data obtained by measuring surface states of the first regions immediately after the formation of AlO films with an X-ray photoelectron spectroscopy (XPS) device for Example 4 and Comparative Example 5.

### DETAILED DESCRIPTION

Hereinafter, embodiments of the present disclosure will be described with reference to the drawings. In each drawing, the same or corresponding components may be denoted by the same reference numerals, and a description thereof may be omitted.

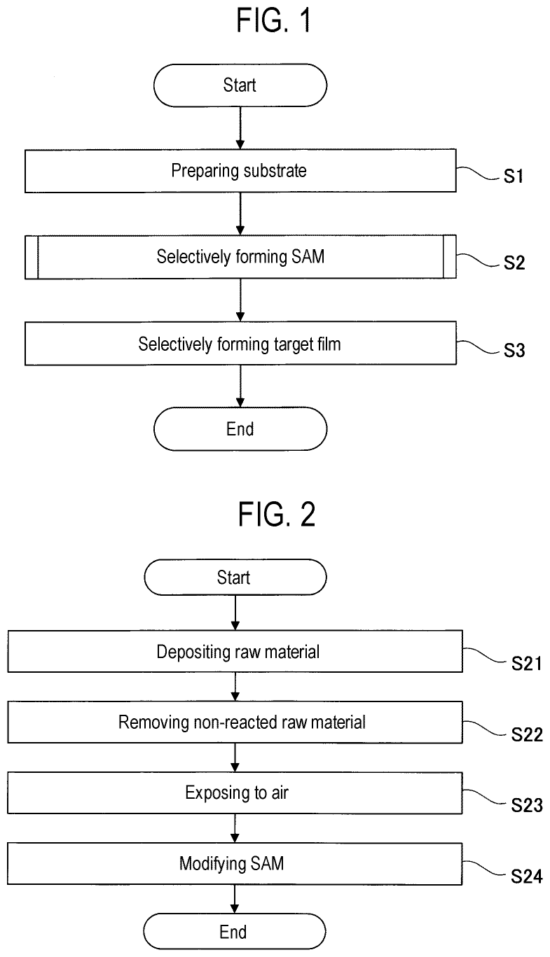

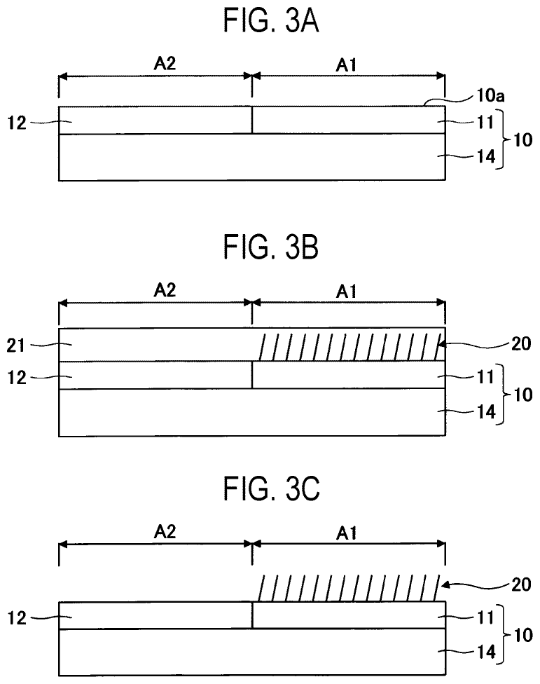

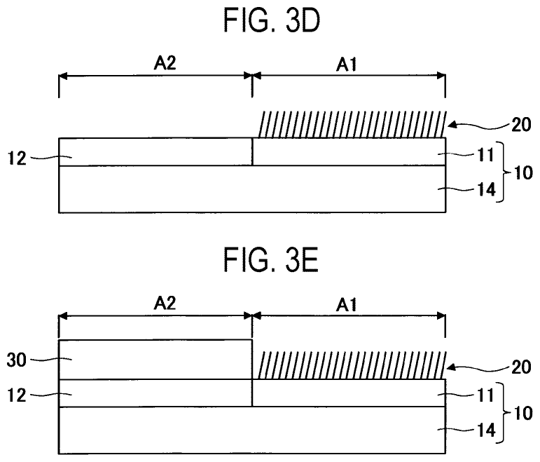

As illustrated in FIG. 1, the film formation method includes S1 to S3. First, in S1 of FIG. 1, a substrate 10 illustrated in FIG. 3A is prepared. The substrate 10 includes, on a surface 10a thereof, a first region A1 in which a first material is exposed and a second region A2 in which a second material different from the first material is exposed. The first region A1 and the second region A2 are provided on one side of the substrate 10 in the plate thickness direction.

The number of first areas A1 is one in FIG. 3A, but may be two or more. For example, two first regions A1 may be arranged with a second region A2 interposed therebetween. Similarly, the number of second regions A2 is one in FIG. 3A, but may be two or more. For example, two second regions A2 may be arranged with a first region A1 interposed therebetween. The first region A1 and the second region A2 are adjacent to each other, but may be spaced apart from each other.

In addition, the substrate 10 illustrated in FIG. 3A includes, on the surface 10a thereof, the first region A1 and the second region A2 only, but may additionally include a third region. The third region is a region in which a third material different from the first material and the second material is exposed. The third region may be arranged between the first region A1 and the second region A2, or may be arranged outside the first region A1 and the second region A2.

The first material is, for example, a metal. The metal is, for example, Cu, W, Co, or Ru. The first material is a metal in the present embodiment, but may be a semiconductor. The semiconductor is, for example, amorphous silicon or polycrystalline silicon. The semiconductor may or may not contain a dopant.

The second material is, for example, an insulating material. The insulating material is, for example, a metal compound or carbon. The metal compound is silicon oxide, silicon nitride, silicon oxinitride, silicon carbide, aluminum oxide, zirconium oxide, hafnium oxide, or the like. The insulating material may be a low-dielectric constant material (low-k material) having a dielectric constant lower than that of SiO₂.

The substrate 10 includes, for example, an insulating film 12 formed of the above-mentioned insulating material and a metal film 11 formed of the above-mentioned metal. Instead of the metal film 11, a semiconductor film formed of the above-mentioned semiconductor may be formed. The substrate 10 includes a base substrate 14 on which the insulating film 12 and the metal film 11 are formed. The base substrate 14 is, for example, a semiconductor substrate such as a silicon wafer. In addition, the base substrate 14 may be a glass substrate or the like.

In addition, the substrate 10 may further include, between the base substrate 14 and the insulating film 12, a base film formed of a material different from those of the base substrate 14 and the insulating film 12. Similarly, the substrate 10 may further include, between the base substrate 14 and the metal film 11, a base film formed of a material different from those of the base substrate 14 and the metal film 11.

Next, in S2 of FIG. 1, as illustrated in FIGS. 3B to 3D, a self-assembled monolayer (SAM) 20 is selectively formed in the first region A1, among the first region A1 and the second region A2. In a portion of the SAM 20, another mono-molecular film may be mixed, or plural molecular films may be formed. S2 in FIG. 1 includes, for example, S21 to S24 illustrated in FIG. 2.

First, in S21 of FIG. 2, as illustrated in FIG. 3B, by using a first processing liquid containing a first raw material 21 of the SAM 20, the first raw material 21 is deposited on the surface 10a of the substrate 10. For example, the vapor of the first processing liquid is supplied to the surface 10a of the substrate 10, and the first raw material 21 is deposited on the surface 10a of the substrate 10. The first raw material 21 is an organic compound, for example, a thiol compound.

The thiol compound is, for example, a compound represented by a general formula, R-SH. Here, R is an aliphatic hydrocarbon group or an aromatic hydrocarbon group, and some of hydrogen atoms may be replaced with halogen atoms. The halogen includes fluorine, chlorine, bromine, iodine, and the like. The thiol compound is, for example, CF₃(CF₂)_{X}(CH₂)₂SH(X=0 to 17) or CH₃(CH₂)_{X}SH (X=1 to 19).

The number of carbon atoms in the main chain of the thiol compound is, for example, 20 or less, preferably 10 or less. The smaller the number of carbon atoms, the shorter the length of the main chain and the higher the vapor pressure. Therefore, the smaller the number of carbon atoms, the supply amount of vapor is likely to increase.

The thiol compound is not chemisorbed to the above-mentioned insulating material, but is chemisorbed to the above-mentioned metal or semiconductor. For example, the thiol compound reacts with the above-mentioned metal or semiconductor to form an R-S-M bond. Here, M is the above-mentioned metal or semiconductor. Since the thiol compound reacts with the above-mentioned metal or semiconductor, the thiol compound is selectively chemisorbed on the first region A1 among the first region A1 and the second region A2.

The first processing liquid contains, for example, a solvent for dissolving the first raw material 21 in addition to the first raw material 21 of the SAM 20. The first raw material 21 may be a liquid or a solid at a room temperature and pressure. The solvent is appropriately selected according to the first raw material 21, and is, for example, toluene or the like. The boiling point of the solvent is, for example, 40 degrees C. to 120 degrees C. The concentration of the first raw material 21 in the first processing liquid is, for example, 0.1% by volume to 10% by volume.

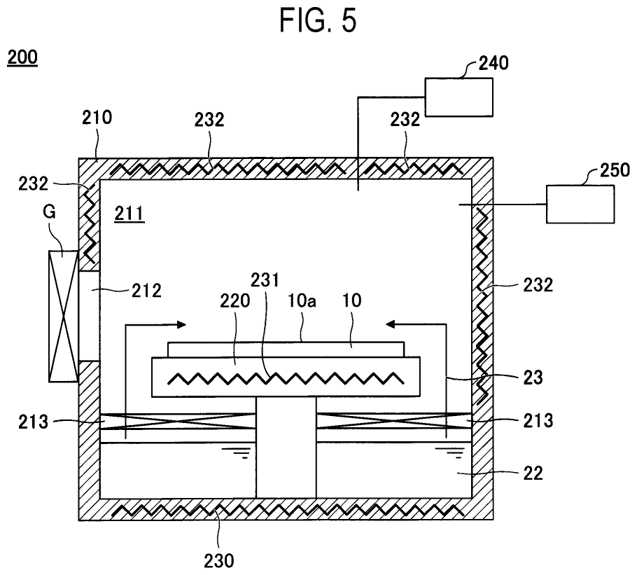

For example, in S21 of FIG. 2, as illustrated in FIG. 5, both the substrate 10 and the first processing liquid 22 may be accommodated inside a first processing container 210, and the vapor 23 of the first processing liquid 22 may be supplied to the surface 10a of the substrate 10. In this case, the substrate 10 is disposed, for example, above the liquid surface of the first processing liquid 22 so as not to get wet with the droplets of the first processing liquid 22.

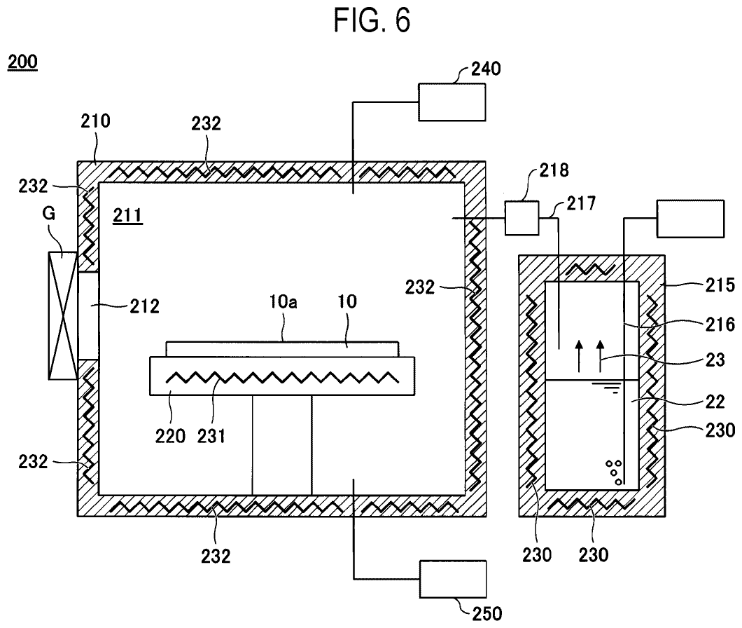

Alternatively, in S21 of FIG. 2, as illustrated in FIG. 6, vapor 23 may be generated inside a second processing container 215 that accommodates the first processing liquid 22, and the generated vapor 23 may be sent from the second processing container 215 to the first processing container 210 that accommodates the substrate 10. Since the second processing container 215 is provided outside the first processing container 210, it is easy to control the temperature T1 of the substrate 10 and the temperature T0 of the first processing liquid 22 separately.

In addition, as illustrated in FIG. 6, the first processing liquid 22 may be bubbled inside the second processing container 215. A bubbling pipe 216 supplies an inert gas such as nitrogen gas or argon gas into the first processing liquid 22 and forms bubbles inside the first processing liquid 22. The bubbling of the first processing liquid 22 may promote the production of the vapor 23.

In S21 of FIG. 2, the temperature T1 of the substrate 10 may be controlled to a temperature higher than the temperature T0 of the first processing liquid 22. Since the vapor 23 is generated at the temperature T0, the vapor 23 may be liquefied at a temperature lower than the temperature T0. When the temperature T1 of the substrate 10 is higher than the temperature T0 of the first processing liquid 22, it is possible to prevent the liquefaction of the vapor 23 on the surface 10a of the substrate 10, and thus it is possible to prevent the adhesion of droplets.

In S21 of FIG. 2, the temperature T2 of the portion of the inner wall surface of the first processing container 210 that comes into contact with the vapor 23 may be controlled to a temperature higher than the temperature T0 of the first processing liquid 22. The first processing container 210 accommodates the substrate 10. When the temperature T2 of the inner wall surface of the first processing container 210 is higher than the temperature T0 of the first processing liquid 22, it is possible to prevent the liquefaction of the vapor 23 on the inner wall surface of the first processing container 210, and thus it is possible to prevent the adhesion of droplets.

The temperature T0 of the first processing liquid 22 is, for example, 20 degrees C. to 110 degrees C. The temperature T1 of the substrate 10 is, for example, 10 degrees C. to 200 degrees C., preferably 60 degrees C. to 200 degrees C. The temperature T2 of the portion of the inner wall surface of the first processing container 210 that comes into contact with the vapor 23 is, for example, 10 degrees C. to 200 degrees C., preferably 60 degrees C. to 200 degrees C. The time for supplying the vapor 23 to the surface 10a of the substrate 10 in S21 of FIG. 2 is, for example, 60 seconds to 300 seconds.

In S21 of the present embodiment, the vapor 23 of the first processing liquid 22 is supplied to the surface 10a of the substrate 10, but the supply method thereof is not particularly limited. Instead of the vapor 23 of the first processing liquid 22, the first processing liquid 22 itself may be supplied to the surface 10a of the substrate 10. Specifically, for example, the first processing liquid 22 may be applied to the surface 10a of the substrate 10 through a dip coating method or a spin coating method. However, when the vapor 23 of the first processing liquid 22 is supplied to the surface 10a of the substrate 10, the blocking performance of the SAM 20 can be improved compared with supplying the first processing liquid 22 itself to the surface 10a of the substrate 10. This is because the substrate 10 is exposed to the vapor 23 while being heated, so that the reaction between the thiol compound and the above-mentioned metal or semiconductor proceeds at the same time as the exposure, an R-S-M bond proceeds, and a strong bond is obtained.

Next, in S22 of FIG. 2, as illustrated in FIG. 3C, the first raw material 21 deposited on the surface 10a of the substrate 10 and unreacted on the surface 10a is removed. The removal of the unreacted first raw material 21 includes, for example, cleaning the surface 10a of the substrate 10 with a solvent that dissolves the first raw material 21. The solvent may be heated to improve the detergency thereof. The heating temperature of the solvent is, for example, 65 degrees C. to 85 degrees C. Since the reaction of the SAM 20 formed in the first region A1 in S21 of FIG. 2 has already been completed, the SAM 20 is not dissolved in the solvent.

Removing the first raw material 21 may include heating the substrate 10 in a pressure-reduced atmosphere having a pressure lower than atmospheric pressure to vaporize the unreacted first raw material 21, instead of cleaning the surface 10a of the substrate 10 with a solvent that dissolves the first raw material 21. The heating temperature of the substrate 10 is, for example, about 100 degrees C. Since the reaction of the SAM 20 formed in the first region A1 in S21 of FIG. 2 has already been completed, the SAM 20 is not vaporized.

S2 of the present embodiment includes S21 to S22 in FIG. 2, but S21 may be included, and S22 may not be included. For example, in S21, when the substrate 10 is heated while evacuating the interior of the first processing container 210 with a vacuum pump or the like, since the unreacted first raw material 21 may be discharged to the exterior of the first processing container 210 in the state of vapor and the SAM 20 can be selectively formed in the first region A1, S22 is unnecessary. However, in S21 of FIG. 2, when the interior of the first processing container 210 is not evacuated by a vacuum pump or the like, there is an advantage in that no vacuum equipment becomes necessary.

Next, in S23 of FIG. 2, the surface 10a of the substrate 10 is exposed to the air atmosphere. The air atmosphere causes the portion of the first region A1 in which the SAM 20 is not formed (hereinafter, also referred to as an “unreacted portion of the first region A1”) to undergo natural oxidation. Since it is possible to appropriately oxidize the above-mentioned metal or semiconductor, the modification of the SAM 20, which will be described later, can be promoted. This is because an appropriately oxidized metal or semiconductor and a thiol compound are likely to form an R-S-M bond by a dehydration reaction.

Next, in S24 of FIG. 2, a second processing liquid containing the second raw material of the SAM 20 at a concentration different from that of the first processing liquid 22 is used, and as illustrated in FIG. 3D, the formed SAM 20 is modified by using the first processing liquid 22. The thiol compound in the second processing liquid is chemisorbed on the unreacted portion of the first region A1 to increase the surface density of the SAM 20. Therefore, the blocking performance of the SAM 20 can be improved.

The first raw material 21 of the first processing liquid 22 and the second raw material of the second processing liquid may be the same as or different from each other. That is, the thiol compound of the first processing liquid 22 and the thiol compound of the second processing liquid may be the same as or different from each other. As the thiol compound, a compound suitable for the supply method is selected. The concentration of the first raw material 21 in the first processing liquid 22 and the concentration of the second raw material in the second processing liquid may be different from each other.

The concentration of the thiol compound in the second processing liquid is preferably higher than the concentration of the thiol compound in the first processing liquid 22. The vapor having a high concentration of the thiol compound may be supplied to the surface 10a of the substrate 10, and the thiol compound may be allowed to enter the unreacted portion of the first region A1, so that the surface density of the SAM 20 can be efficiently increased.

For example, the first processing liquid 22 is a solution containing a solvent, whereas the second processing liquid is an undiluted solution containing no solvent. The undiluted solution contains only a thiol compound. The thiol compound is in a state of 100% purity. The thiol compound may be a solid rather than a liquid. The vapor of the solid may be supplied to the surface 10a of the substrate 10.

In the present embodiment, the vapor of the second processing liquid is supplied to the surface 10a of the substrate 10. In this case, a thiol compound having a small number of carbon atoms in the main chain is selected so that the supply amount of vapor can be easily increased. In addition, when the number of carbon atoms in the main chain is small, the length of the main chain is short, so the thiol compound easily enters the unreacted portion of the first region A1.

Next, in S3 of FIG. 1, as illustrated in FIG. 3E, a desired target film 30 is formed in the second region A2, among the first region A1 and the second region A2, by using the SAM 20 formed in the first region A1. The target film 30 is made of a material different from that of the SAM 20. Since the SAM 20 has, for example, hydrophobicity and inhibits formation of the target film 30, the target film 30 is selectively formed in the second region A2.

The target film 30 is formed through, for example, a chemical vapor deposition (CVD) method or an atomic layer deposition (ALD) method. The target film 30 is formed of, for example, an insulating material. An insulative target film 30 may be further laminated on the insulating film 12 originally existing in the second region A2. The insulative target film 30 is formed of, for example, a metal compound. The metal compound is, for example, a metal oxide or a metal oxynitride. The metal oxynitride is, for example, silicon oxynitride.

The insulative target film 30 is not particularly limited, but is formed of, for example, aluminum oxide. Hereinafter, aluminum oxide is also referred to as “AlO” regardless of the composition ratio of oxygen and aluminum. When an AlO film is formed as the target film 30 through the ALD method, an Al-containing gas, such as trimethylaluminum (TMA: (CH₃)₃Al) gas, and an oxidizing gas, such as water vapor (H₂O in a gas state), are alternately supplied to the substrate 10. Since water vapor is not adsorbed on the hydrophobic SAM 20, AlO is selectively deposited in the second region A2. In addition to the Al-containing gas and the oxidizing gas, a modifying gas, such as hydrogen (H₂) gas, may be supplied to the substrate 10. These gases may be plasmatized to promote a chemical reaction. In addition, these gases may be heated to promote a chemical reaction.

The insulative target film 30 may be formed of hafnium oxide. Hereinafter, hafnium oxide is also referred to as “HfO” regardless of the composition ratio of oxygen and hafnium. When an HfO film is formed as the target film 30 through the ALD method, an Hf-containing gas, such as tetrakis(dimethylamide)hafnium (TDMAH: Hf[N(CH₃)₂]₄) gas, and an oxidizing gas, such as water vapor (H₂O in a gas state), are alternately supplied to the substrate 10. Since the water vapor is not adsorbed on the hydrophobic SAM 20, HfO is selectively deposited in the second region A2. In addition to the Hf-containing gas and the oxidizing gas, a modifying gas such as hydrogen (H₂) gas may be supplied to the substrate 10. These gases may be plasmatized to promote a chemical reaction. In addition, these gases may be heated to promote a chemical reaction.

The insulating target film 30 may be formed of vanadium nitride. Hereinafter, vanadium nitride is also referred to as “VN” regardless of the composition ratio of nitrogen and vanadium. When a VN film is formed as the target film 30 through the ALD method, a V-containing gas, such as tetrakis(ethylmethylamino)vanadium (V[N(CH₃)C₂H₅]₄) gas, and a nitriding gas, such as an ammonia gas (NH₃ gas), are alternately supplied to the substrate 10. The VN is selectively deposited in the second region A2. In addition to the V-containing gas and the nitride gas, a modifying gas, such as hydrogen (H₂) gas may be supplied to the substrate 10. These gases may be plasmatized to promote a chemical reaction. In addition, these gases may be heated to promote a chemical reaction.

In the above-described embodiment, the first material of the first region A1 is a metal or a semiconductor, the second material of the second region A2 is an insulating material, and the first raw material 21 and the second raw material of the SAM 20 are thiol compounds. However, the techniques of the present disclosure are not limited to this combination. For example, the first material of the first region A1 may be an insulating material, the second material of the second region A2 may be a metal or a semiconductor, and the first raw material 21 and the second raw material of the SAM 20 may be a silane compound.

The silane compound is, for example, a compound represented by the general formula R-SiH₃₋ₓClₓ (x=1, 2, 3) or a compound represented by R′—Si(O—R)₃ (silane coupling agent). Here, R and R′ are functional groups such as an alkyl group or a group in which at least some of hydrogen atoms of the alkyl group is substituted with fluorine atoms. The terminal group of the functional group may be either CH-based or CF-based. In addition, O-R is a hydrolyzable functional group, such as a methoxy group or an ethoxy group. An example of the silane coupling agent includes octamethyltrimethoxysilane (OTS).

A silane compound is more likely to be chemisorbed on a surface with OH groups, so the silane compound is more likely to be chemisorbed on a metal compound or carbon than a metal or a semiconductor. Therefore, the silane compound is selectively chemisorbed in the first region A1, among the first region A1 and the second region A2. As a result, the SAM 20 is selectively formed in the first region A1.

When the first raw material 21 and the second raw material of SAM 20 are silane compounds, the target film 30 is formed of, for example, a conductive material. The conductive target film 30 may be further laminated on the conductive metal film originally existing in the second region A2. The conductive target film 30 is formed of, for example, a metal, a metal compound, or a semiconductor containing a dopant.

As described above, a semiconductor film may originally exist in the second region A2 instead of the metal film, and the semiconductor film may contain a dopant or may be imparted with conductivity. The conductive target film 30 may be laminated on the conductive semiconductor film.

The conductive target film 30 is not particularly limited, but is formed of, for example, a titanium nitride. Hereinafter, the titanium nitride is also referred to as “TiN” regardless of the composition ratio of nitrogen and titanium. When the TiN film is formed as the target film 30 through the ALD method, a Ti-containing gas, such as tetrakis(dimethylamino)titanium (TDMA: Ti[N(CH₃)₂]₄) gas or titanium tetrachloride (TiCl₄) gas, and a nitriding gas, such as ammonia (NH₃) gas, are alternately supplied to the substrate 10. In addition to the Ti-containing gas and the nitriding gas, a modifying gas, such as hydrogen (H₂) gas, may be supplied to the substrate 10. These gases may be plasmatized to promote a chemical reaction. In addition, these gases may be heated to promote a chemical reaction.

The film formation method may further include a process other than the process illustrated in FIG. 1. For example, in the film formation method, foreign matter adhering to the surface 10a of the substrate 10 may be removed with a cleaning liquid as a pre-treatment before S1 in FIG. 1. As a cleaning liquid for removing an organic substance, for example, an aqueous solution of hydrogen peroxide (H₂O₂) is used. As a cleaning liquid for removing cupric benzotriazole (C₆H₄N₃)₂Cu) formed by an antioxidant added to slurry through chemical mechanical polishing (CMP) performed before S1 in FIG. 1 and a natural oxide film on a surface of a metal film 11 (or a semiconductor film), an aqueous solution of formic acid (HCOOH) or citric acid (C(OH)(CH₂COOH)₂COOH) is used. The substrate 10 is cleaned with a cleaning liquid, dried, and provided to S2.

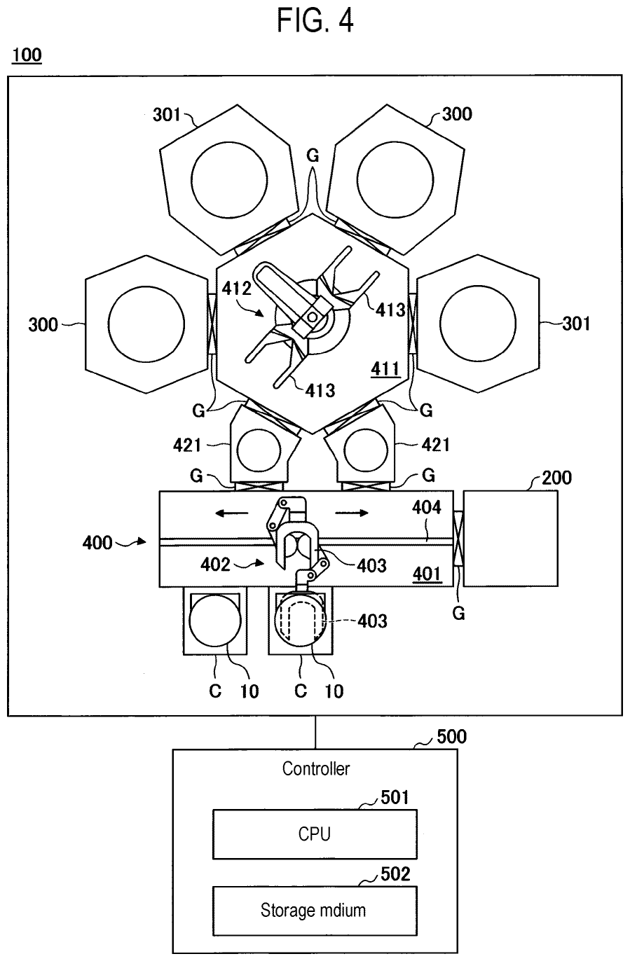

Next, with reference to FIG. 4, a film formation apparatus 100 that implements the above-described film formation method will be described. As illustrated in FIG. 4, the film formation apparatus 100 includes a first processor 200, a second processor 300, a third processor 301, a transporter 400, and a controller 500. The first processor 200 selectively forms the SAM 20 in the first region A1, among the first region A1 and the second region A2, by using the first processing liquid 22 containing the first raw material 21 of the SAM 20. The second processor 300 modifies the SAM 20 formed by the first processor 200 by using the second processing liquid containing the second raw material of the SAM 20 at a concentration different from that of the first processing liquid 22. The third processor 301 selectively forms the desired target film 30 in the second region A2 by using the SAM 20 modified by the second processor 300. The transporter 400 transports the substrate 10 with respect to the first processor 200, the second processor 300, and the third processor 301. The controller 500 controls the first processor 200, the second processor 300, the third processor 301, and the transporter 400.

The transporter 400 includes a first transport chamber 401 and a first transport mechanism 402. The internal atmosphere of the first transport chamber 401 is an air atmosphere. The first transport mechanism 402 is provided inside the first transport chamber 401. The first transport mechanism 402 includes an arm 403 that holds the substrate 10 and travels along a rail 404. The rail 404 extends in an arrangement direction of carriers C. The first processor 200 is connected to the first transport chamber 401 via a gate valve G. The gate valve G opens/closes a transport path of the substrate 10. The gate valve G basically blocks the transport path, and opens the transport path only when the substrate 10 passes through the gate valve G.

The transporter 400 includes a second transport chamber 411 and a second transport mechanism 412. The internal atmosphere of the second transport chamber 411 is a vacuum atmosphere. The second transport mechanism 412 is provided inside the second transport chamber 411. The second transport mechanism 412 includes an arm 413 that holds the substrate 10, and the arm 413 is disposed to be movable in the vertical direction and the horizontal direction and to be rotatable around the vertical axis. The second processor 300 and the third processor 301 are connected to the second transport chamber 411 via different gate valves G, respectively.

The transporter 400 includes load-lock chambers 421 between the first transport chamber 401 and the second transport chamber 411. The internal atmosphere of the load-lock chambers 421 is switched between a vacuum atmosphere and an air atmosphere. As a result, the interior of the second transport chamber 411 may always be maintained in a vacuum atmosphere. In addition, it is possible to suppress the inflow of gas from the first transport chamber 401 to the second transport chamber 411. Gate valves G are provided between the first transport chamber 401 and the load-lock chamber 421, and between the second transport chamber 411 and the load-lock chamber 421.

The controller 500 is, for example, a computer, and includes a central processing unit (CPU) 501 and a storage medium 502 such as a memory. The storage medium 502 stores programs that control various processes executed by the film formation apparatus 100. The controller 500 controls the operation of the film formation apparatus 100 by causing the CPU 501 to execute the programs stored in the storage medium 502.

Next, the operation of the film formation apparatus 100 will be described. First, the first transport mechanism 402 unloads the substrate 10 from the carrier C and transports the unloaded substrate 10 to the first processor 200. The first processor 200 executes S21 to S22 of FIG. 2. That is, the first processor 200 selectively forms the SAM 20 in the first region A1, among the first region A1 and the second region A2.

Next, the first transport mechanism 402 unloads the substrate 10 from the first processor 200, and exposes the substrate 10 to the air atmosphere while transporting the substrate 10 in the first transport chamber 401. As a result, S23 in FIG. 2 is executed. Thereafter, the first transport mechanism 402 transports the substrate 10 to a load-lock chamber 421 and exits from the load-lock chamber 421.

Next, the internal atmosphere of the load-lock chamber 421 is switched from the air atmosphere to the vacuum atmosphere. Thereafter, the second transport mechanism 412 unloads the substrate 10 from the load-lock chamber 421 and transports the unloaded substrate 10 to the second processor 300.

Next, the second processor 300 executes S24 in FIG. 2. That is, the second processor 300 modifies the SAM 20 formed by the first processor 200. It is possible to improve the surface density of the SAM 20, and to improve the blocking performance of the SAM 20.

Next, the second transport mechanism 412 unloads the substrate 10 from the second processor 300, and transports the unloaded substrate 10 to the third processor 301. During this period, the surrounding atmosphere of the substrate 10 can be maintained in a vacuum atmosphere so that deterioration of the blocking performance of the SAM 20 after modification can be suppressed.

Next, the third processor 301 executes S3 in FIG. 1. That is, the third processor 301 selectively forms the desired target film 30 in the second region A2 by using the SAM 20 modified by the second processor 300.

Next, the second transport mechanism 412 unloads the substrate 10 from the third processor 301, transports the unloaded substrate 10 to the load-lock chamber 421, and exits from the load-lock chamber 421. Subsequently, the internal atmosphere of the load-lock chamber 421 is switched from the vacuum atmosphere to the air atmosphere. Thereafter, the first transport mechanism 402 unloads the substrate 10 from the load-lock chamber 421 and accommodates the unloaded substrate 10 in the carrier C.

The configuration of the film formation apparatus 100 is not limited to the configuration illustrated in FIG. 4. For example, the first processor 200 may not be installed adjacent to the first transport chamber 401, but may be separately provided as one apparatus. In the latter case, after the substrate 10 is processed by the first processor 200, the substrate 10 is accommodated in the carrier C, and then is transported from the carrier C to the load-lock chamber 421.

Next, the first processor 200 will be described with reference to FIG. 5. The first processor 200 includes a first processing container 210, a substrate holder 220, a first temperature regulator 230, a second temperature regulator 231, a third temperature regulator 232, a gas supplier 240, and a gas discharger 250. The first processing container 210 accommodates both the substrate 10 and the first processing liquid 22. The substrate holder 220 holds the substrate 10 inside the first processing container 210. The first temperature regulator 230 regulates the temperature of the first processing liquid 22. The second temperature regulator 231 adjusts the temperature of the substrate 10. The third temperature regulator 232 adjusts the temperature of the portion to be in contact with vapor 23 in the inner wall surface of the first processing container 210. The gas supplier 240 supplies a gas, such as an inert gas, into the first processing container 210. The gas discharger 250 discharges gas from the interior of the first processing container 210.

The first processing container 210 includes a carry-in/out port 212 of a substrate 10. The carry-in/out port 212 is disposed at a position higher than the liquid level of the first processing liquid 22. The carry-in/out port 212 is provided with a gate valve G that opens/closes the carry-in/out port 212. The gate valve G basically closes the carry-in/out port 212, and opens the carry-in/out port 212 when the substrate 10 passes through the carry-in/out port 212. When the carry-in/out port 212 is opened, the processing chamber 211 inside the first processing container 210 and the first transport chamber 401 communicate with each other.

The first processing container 210 may include a switch 213 that opens/closes a vapor 23 passage. When the switch 213 opens the passage, the vapor 23 flows from the liquid level of the first processing liquid 22 toward the substrate 10, and the vapor is supplied to the surface 10a of the substrate 10. When the switch 213 closes the passage, the supplying of vapor 23 to the substrate 10 is interrupted. When the switch 213 closes the vapor 23 passage at the time of carry-in/out of the substrate 10 with respect to the first processing container 210, and an inert gas, such as Ar or N₂, is supplied from the gas supplier 240 while the vapor 23 is exhausted by using the gas discharger 250, it is possible to suppress the exposure of the arm 403 of the first transport mechanism 402 to the vapor 23.

The substrate holder 220 holds the substrate 10 inside the first processing container 210. The substrate 10 is disposed above the liquid level of the first processing liquid 22 so as not to become wet with the first processing liquid 22. The substrate holder 220 holds the substrate 10 horizontally from below the substrate 10 such that the surface 10a of the substrate 10 faces upward. The substrate holder 220 is a single-wafer type and holds one substrate 10. The substrate holder 220 may be of a batch type and may hold plural substrates 10 at the same time. The batch-type substrate holder 220 may hold plural substrates 10 at intervals in the vertical direction or at intervals in the horizontal direction.

The first temperature regulator 230, the second temperature regulator 231, and the third temperature regulator 232 each include, for example, an electric heater and are independently controlled. The first temperature regulator 230 is embedded in, for example, the bottom wall or the like of the first processing container 210 and heats the bottom wall to heat the first processing liquid 22 to a desired temperature. In addition, the second temperature regulator 231 is embedded in, for example, the substrate holder 220 and heats the substrate holder 220 to heat the substrate 10 to a desired temperature. Furthermore, the third temperature regulator 232 is embedded in the side wall and the ceiling of the first processing container 210, and by heating the side wall and the ceiling, the portions to be in contact with the vapor 23 in the inner wall surfaces of the side wall and the ceiling are heated to a desired temperature.

The first temperature regulator 230, the second temperature regulator 231, and the third temperature regulator 232 are not limited to the arrangement illustrated in FIG. 5. For example, the first temperature regulator 230 may be immersed in the first processing liquid 22. The second temperature regulator 231 may include a lamp configured to heat the substrate holder 220 through a quartz window. The third temperature regulator 232 may be installed outside the first processing container 210.

The gas supplier 240 and the gas discharger 250 adjust the atmosphere inside the first processing container 210 at the time of carry-in/out of the substrate 10, and lower the concentration of the vapor 23 compared with that at the time of deposition of the first raw material 21. The arm 403 of the first transport mechanism 402 can be suppressed from being exposed to the vapor 23.

The first processor 200 executes S21 in FIG. 2 by supplying the vapor 23 of the first processing liquid 22 to the surface 10a of the substrate 10. In addition, the first processor 200 executes S22 in FIG. 2 by turning the ambient atmosphere of the substrate 10 into a pressure-reduced atmosphere by the gas discharger 250 and heating the substrate 10 by the second temperature regulator 231.

The first processor 200 may further include a nozzle (not illustrated) in order to execute S22 in FIG. 2. The nozzle ejects a solvent for dissolving the first raw material 21 toward the surface 10a of the substrate 10. The same applies to the first processor 200 illustrated in FIG. 6 to be described later.

Next, a modification of the first processor 200 will be described with reference to FIG. 6. The first processor 200 includes a first processing container 210, a second processing container 215, a substrate holder 220, a first temperature regulator 230, a second temperature regulator 231, a third temperature regulator 232, a gas supplier 240, and a gas discharger 250. The first processing container 210 accommodates a substrate 10, and the second processing container 215 accommodates a first processing liquid 22. Hereinafter, the differences between the first processor 200 of the present modification and the first processor 200 of FIG. 5 will be mainly described.

The second processing container 215 is disposed outside the first processing container 210. Therefore, it is easy to control the temperature T1 of the substrate 10 and the temperature T0 of the first processing liquid 22 separately. In addition, it is easy to separately control the temperature T2 of the inner wall surface of the first processing container 210 and the temperature T0 of the first processing liquid 22. The first temperature regulator 230 is provided in, for example, the bottom wall, the side wall, and the ceiling of the second processing container 215, and heats the first processing liquid 22 to a desired temperature by heating the bottom wall, the side wall, and the ceiling. The first temperature regulator 230 may be immersed in the first processing liquid 22.

The first processor 200 may further include a bubbling pipe 216. The bubbling pipe 216 supplies an inert gas, such as nitrogen gas or argon gas, into the first processing liquid 22, and forms bubbles inside the first processing liquid 22. By the bubbling of the first processing liquid 22, the generation of the vapor 23 can be promoted. The vapor 23 is sent from the second processing container 215 to the first processing container 210 via a pipe 217. An opening/closing valve 218 may be provided in the middle of the pipe 217.

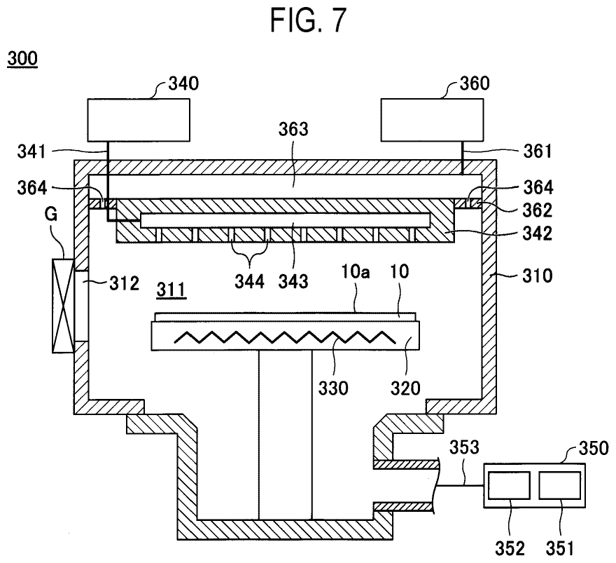

Next, the second processor 300 will be described with reference to FIG. 7. The second processor 300 includes a processing container 310, a substrate holder 320, a temperature regulator 330, a gas supplier 340, and a gas discharger 350. The processing container 310 accommodates the substrate 10. The substrate holder 320 holds the substrate 10 inside the processing container 310. The temperature regulator 330 regulates the temperature of the substrate 10. The gas supplier 340 supplies gas into the processing container 310. The gas contains the vapor of the second processing liquid. The gas discharger 350 discharges the gas from the interior of the processing container 310.

The processing container 310 includes a carry-in/out port 312 of the substrate 10. The carry-in/out port 312 is provided with a gate valve G that opens/closes the carry-in/out port 312. The gate valve G basically closes the carry-in/out port 312, and opens the carry-in/out port 312 when the substrate 10 passes through the carry-in/out port 312. When the carry-in/out port 312 is opened, the processing chamber 311 inside the processing container 310 and the second transport chamber 411 communicate with each other.

The substrate holder 320 holds the substrate 10 inside the processing container 310. The substrate holder 320 holds the substrate 10 horizontally from below such that the surface 10a of the substrate 10 faces upward. The substrate holder 320 is of a single-wafer type and holds one substrate 10. The substrate holder 320 may be of a batch type and may hold plural substrates 10 at the same time. The batch-type substrate holder 320 may hold plural substrates 10 at intervals in the vertical direction or at intervals in the horizontal direction.

The temperature regulator 330 regulates the temperature of the substrate 10. The temperature regulator 330 includes, for example, an electric heater. The temperature regulator 330 is embedded in, for example, the substrate holder 320 and heats the substrate holder 320 to heat the substrate 10 to a desired temperature. The temperature regulator 330 may include a lamp configured to heat the substrate holder 320 through a quartz window. In this case, an inert gas, such as argon gas, may be supplied to a space between the substrate holder 320 and the quartz window in order to prevent the quartz window from becoming opaque due to deposits. The temperature regulator 330 may be installed outside the processing container 310 and may regulate the temperature of the substrate 10 from the exterior of the processing container 310.

The gas supplier 340 supplies a preset gas to the substrate 10. The gas supplier 340 is connected to the processing container 310 via, for example, a gas supply pipe 341. The gas supplier 340 includes gas supply sources, an individual pipe individually extending from each gas source to the gas supply pipe 341, an opening/closing valve provided in the middle of the individual pipe, and a flow rate controller provided in the middle of the individual pipe. When the opening/closing valve opens the individual pipe, a gas is supplied from the gas source thereof to the gas supply pipe 341. The supply amount of the processing gas is controlled by the flow rate controller. Meanwhile, when the opening/closing valve closes the individual pipe, the supplying of the gas from the gas source thereof to the gas supply pipe 341 is stopped.

The gas supply pipe 341 supplies the gas supplied from the gas supplier 340 into the processing container 310. The gas supply pipe 341 supplies the gas supplied from the gas supplier 340 to, for example, a shower head 342. The shower head 342 is provided above the substrate holder 320. The shower head 342 includes a space 343 therein, and ejects the gas stored in the space 343 vertically downward from a large number of gas ejection holes 344. A gas in a shower form is supplied to the substrate 10.

The second processor 300 may further include a gas supplier 360 in addition to the gas supplier 340. The gas supplier 340 supplies the vapor of the second processing liquid to the processing chamber 311 via the shower head 342. When the third processor 301 is configured in the same manner as the second processor 300 as described later, the gas supplier 340 of the third processor 301 supplies an organometallic gas such as TMA to the processing chamber 311 via the shower head 342. The gas supplier 360 supplies an oxidizing gas, such as H₂O, O₂, or O₃, to the processing chamber 311 via the shower head 362. The two shower heads 342 and 362 are provided separately. Therefore, the mixing of the organometallic gas and the oxidizing gas in these spaces 343 and 363 can be suppressed, and the generation of particles in these spaces 343 and 363 can be suppressed. The gas supplier 360 supplies the oxidizing gas to the shower head 362 via the gas supply pipe 361. Oxidizing gas is supplied from the space 363 inside the shower head 362 to the processing chamber 311 through the gas ejection holes 364.

The gas discharger 350 discharges the gas from the interior of the processing container 310. The gas discharger 350 is connected to the processing container 310 via an exhaust pipe 353. The gas discharger 350 includes an exhaust source 351, such as a vacuum pump, and a pressure controller 352. When the exhaust source 351 is operated, gas is discharged from the interior of the processing container 310. The gas pressure inside the processing container 310 is controlled by the pressure controller 352.

Since the third processor 301 is configured in the same manner as the second processor 300, illustration and description thereof will be omitted. Unlike the second processor 300, the third processor 301 supplies a gas used for CVD or ALD to the surface 10a of the substrate 10 instead of the vapor of the second processing liquid to form the target film 30.

### Example 1 and Comparative Examples 1 and 2

In Example 1, the formation of a SAM 20 using the first processing liquid 22 and the modification of the SAM 20 using the second processing liquid were executed. As the first processing liquid 22, a solution containing 1% by volume of a thiol compound was used, whereas an undiluted solution containing about 100% by volume of a thiol compound was used as the second processing liquid. In Comparative Example 1, only the formation of a SAM using the undiluted solution was executed. In addition, in Comparative Example 2, the formation of a SAM 20 using the undiluted solution and the modification of the SAM 20 using the undiluted solution were executed. The details will be described below.

### Example 1

First, in S1 of FIG. 1, a substrate 10 including, on the surface 10a thereof, a first region A1 in which Cu is exposed and a second region A2 in which SiOC is exposed, was prepared. As a pre-treatment for the selective film formation of the SAM 20, the surface 10a of the substrate 10 was cleaned with a 1% aqueous solution of citric acid at 60 degrees C. for 1 minute. In addition, as the first processing liquid 22, a solution containing 1% by volume of CH₃(CH₂)₅SH as the first raw material 21 and 99% by volume of toluene as the solvent was prepared. In addition, as the second processing liquid, an undiluted solution containing about 100% by volume of CH₃(CH₂)₅SH as the second raw material was prepared. In Example 1, the thiol compound of the second processing liquid and the thiol compound of the first processing liquid were the same.

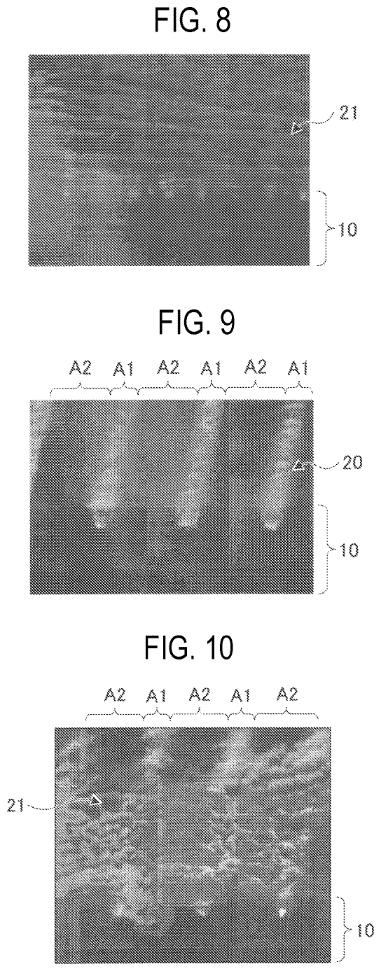

Next, in S21 of FIG. 2, both the substrate 10 and the first processing liquid 22 were accommodated inside the container, and the substrate 10 was disposed above the liquid level of the first processing liquid 22. In that state, the entire container was uniformly heated from the exterior with the heaters. The heating temperature was 85 degrees C., and the heating time was 5 minutes (300 seconds). As a result, the vapor 23 of the first processing liquid 22 was supplied to the surface 10a of the substrate 10. Thereafter, the surface 10a of the substrate 10 was observed with a scanning electron microscope (SEM) and, as shown in FIG. 8, deposition of the first raw material 21 of the SAM 20 was observed in both the first region A1 and the second region A2.

Next, in S 22 of FIG. 2, the substrate 10 was cleaned with toluene at 65 degrees C., and the first raw material 21 deposited on the surface 10a of the substrate 10 and unreacted on the surface 10a was removed. Thereafter, when the surface 10a of the substrate 10 was observed with a scanning electron microscope (SEM), it was confirmed that the SAM 20 was selectively formed in the first region A1 as shown in FIG. 9. It is presumed that the reason why the SAM 20 was not removed by toluene is that CH₃(CH₂)₅SH as the first raw material 21 reacted with Cu to form a bond of CH₃(CH₂)₅S-Cu.

When the substrate 10 was cleaned with toluene at room temperature instead of cleaning with toluene at 65 degrees C., the unreacted first raw material 21 remained in the second region A2 and the like as shown in FIG. 10. Therefore, it can be seen that it is preferable to heat the solvent to 65 degrees C. or higher in order to remove the unreacted first raw material 21.

Next, in S23 of FIG. 2, the surface 10a of the substrate 10 was exposed to the air atmosphere at room temperature for 5 minutes.

Next, in S24 of FIG. 2, while the substrate 10 was accommodated inside the processing container 310 illustrated in FIG. 7, the air pressure inside the processing container 310 was controlled to 900 Pa, and the temperature of the substrate 10 was controlled to 150 degrees C., the vapor of an undiluted solution was supplied to the surface 10 a of the substrate 10 for 1 minute. Thereafter, when the surface 10a of the substrate 10 was observed with a scanning electron microscope (SEM), it was confirmed that the SAM 20 was selectively formed in the first region A1.

Finally, in S3 of FIG. 1, an AlO film was deposited on the surface 10a of the substrate 10 through the ALD method. Specifically, while the air pressure inside the processing container was controlled to 400 Pa and the temperature of the substrate 10 was controlled to 120 degrees C., alternately supplying TMA gas and water vapor to the surface 10a of the substrate 10 was repeated 75 times. Thereafter, when the surface 10a of the substrate 10 was observed with a scanning electron microscope (SEM), it was confirmed that an AlO film was selectively formed in the second region A2. The thickness of the AlO film was 6 nm.

### Comparative Example 1

In Comparative Example 1, the substrate 10 was processed in the same manner as in Example 1, except that only the formation of a SAM using an undiluted solution was executed instead of executing S21 to S24 in FIG. 2. The formation of the SAM using the undiluted solution was executed under the same conditions as in S24 of Example 1. The undiluted solution contained 100% by volume of CH₃(CH₂)₅SH as in the undiluted solution of Example 1.

### Comparative Example 2

In Comparative Example 2, the substrate 10 was processed in the same manner as in Example 1, except that a SAM was formed by using an undiluted solution instead of forming a SAM using the solution in S21 of FIG. 2. The formation of the SAM using the undiluted solution was executed under the same conditions as in S 24 of Example 1. The undiluted solution contained 100% by volume of CH₃(CH₂)₅SH as in the undiluted solution of Example 1. That is, in Comparative Example 2, the vapor of the undiluted solution was supplied twice with exposure to air interposed therebetween.

### Evaluation 1

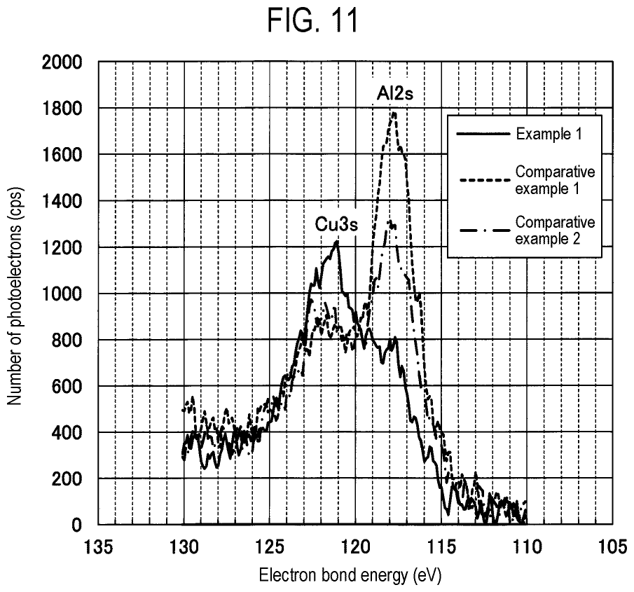

FIG. 11 shows data obtained by measuring the surface states of the first regions A1 immediately after the formation of AlO films with an X-ray photoelectron spectroscopy (XPS) device for Example 1 and Comparative Examples 1 and 2. As is clear from FIG. 11, according to Example 1, since the relative strength of the Cu peak to the Al peak is higher compared to those of Comparative Examples 1 and 2, it can be seen that the film formation of the AlO film was inhibited.

From FIG. 11, it can be seen that, when the formation of the SAM 20 using a solution and the modification of the SAM 20 using an undiluted solution are executed, it is possible to improve the blocking performance of the SAM 20 compared to the case in which the formation of the SAM using the undiluted solution and the modification of the SAM using the undiluted solution as well as the case in which only the formation of the SAM using the undiluted solution is executed.

That is, from FIG. 11, it can be seen that the blocking performance of the SAM 20 can be improved by using the first processing liquid 22 and the second processing liquid having different concentrations.

### Example 2 and Comparative Example 3

In addition to Example 1 above, Example 2 below was executed to investigate the relationship between the number of carbon atoms in the main chain of a thiol compound and the blocking performance of a SAM. In addition to Example 2 below, Comparative Example 3 below was also executed.

### Example 2

In Example 2, the substrate 10 was processed in the same manner as in Example 1, except that the first raw material 21 of the SAM 20 was changed. As the first processing liquid 22, a solution containing 1% by volume of CH₃(CH₂)₁₇SH as the first raw material 21 and 99% by volume of toluene as the solvent was prepared. In addition, as the second processing liquid, an undiluted solution containing 100% by volume of CH₃(CH₂)₁₇SH as the second raw material was prepared. In Example 2, the thiol compound of the second processing liquid and the thiol compound of the first processing liquid were the same.

When the surface 10a of the substrate 10 was observed with a scanning electron microscope (SEM) after S2 and before S3 in FIG. 1, it was confirmed that the SAM was selectively formed in the first region A1. Further, when the surface 10a of the substrate 10 was observed with a scanning electron microscope (SEM) after S3 in FIG. 1, it was confirmed that the AlO film was selectively formed in the second region A2.

### Comparative Example 3

In Comparative Example 3, the substrate 10 was processed in the same manner as in Example 2, except that only the formation of SAM using the undiluted solution was executed instead of executing S21 to S24 in FIG. 2. The formation of the SAM using the undiluted solution was executed under the same conditions as in S24 of Example 2. The undiluted solution contained 100% by volume of CH₃(CH₂)₁₇SH as in the undiluted solution of Example 2.

### Evaluation 2

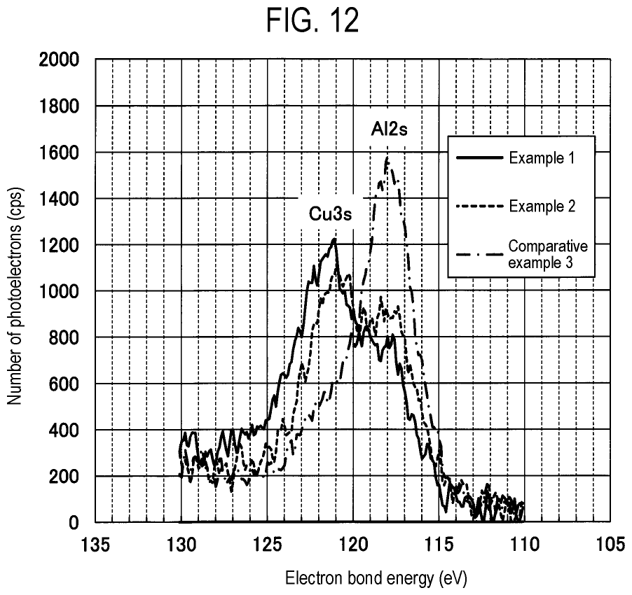

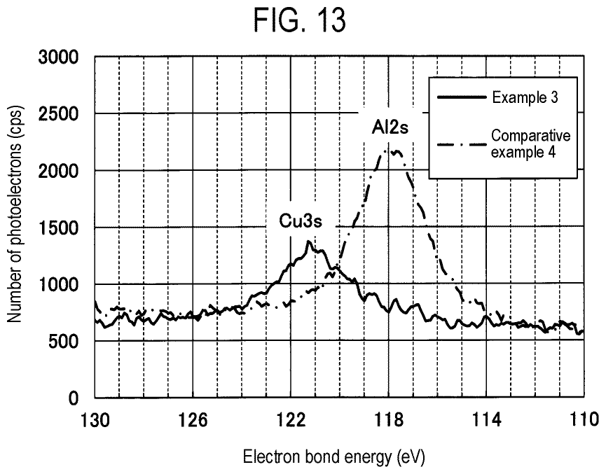

FIG. 12 shows data obtained by measuring the surface states of the first regions A1 immediately after the formation of AlO films with an X-ray photoelectron spectroscopy (XPS) device for Examples 1 and 2 and Comparative Example 3. As is clear from FIG. 12, according to Example 1, since the relative strength of the Cu peak to the Al peak is higher compared to that of Example 2, it can be seen that the film formation of the AlO film was inhibited. Therefore, it can be seen that the blocking performance of the SAM 20 can be improved when the number of carbon atoms in the main chain of the thiol compound is 10 or less.

As is clear from FIG. 12, according to Example 2, since the relative strength of the Cu peak to the Al peak is higher compared to that of Comparative Example 3, it can be seen that the film formation of the AlO film was inhibited. Accordingly, it can be seen that when the formation of the SAM 20 using a solution and the modification of the SAM 20 using an undiluted solution are executed, it is possible to improve the blocking performance of the SAM 20 compared to the case in which only the formation of the SAM using the undiluted solution is executed.

### Example 3 and Comparative Example 4

In Example 3 and Comparative Example 4, unlike Example 1 and the like, the first processing liquid 22 was applied to the surface 10a of the substrate 10 through the dip coating method in S21 of FIG. 2. In Example 3, the formation of a SAM 20 using the first processing liquid 22 and the modification of the SAM 20 using the second processing liquid were executed. Meanwhile, in Comparative Example 4, only the formation of the SAM 20 using the first processing liquid 22 was executed. The details will be described below.

### Example 3

In Example 3, the substrate 10 was processed in the same manner as in Example 1, except that, the first processing liquid 22 was applied to the surface 10a of the substrate 10 through the dip coating method in S21 of FIG. 2 and alternately supplying TMA gas and water vapor to the surface 10 a of the substrate 10 was repeated 40 times at the time of forming an AlO film.

In the dip coating method, the entire substrate 10 was immersed in the first processing liquid 22 at 85 degrees C. for 30 minutes. The first processing liquid 22 was a solution containing 1% by volume of CH₃(CH₂)₅SH and 99% by volume of toluene as the solvent, as in the first processing liquid 22 of Example 1.

The second processing liquid was also an undiluted solution containing 100% by volume of CH₃(CH₂)₅SH, as in the second processing liquid of Example 1. In Example 3, the thiol compound of the second processing liquid and the thiol compound of the first processing liquid were the same.

When the surface 10a of the substrate 10 was observed with a scanning electron microscope (SEM) after S2 and before S3 in FIG. 1, it was confirmed that the SAM was selectively formed in the first region A1. Furthermore, when the surface 10a of the substrate 10 was observed with a scanning electron microscope (SEM) after S3 in FIG. 1, it was confirmed that the AlO film was selectively formed in the second region A2. The thickness of the AlO film was 3 nm.

### Comparative Example 4

In Comparative Example 4, the substrate 10 was processed in the same manner as in Example 4, except that only the formation of a SAM using a solution was executed instead of executing S21 to S24 in FIG. 2. The formation of a SAM using the solution was conducted under the same conditions as in S21 of Example 3. The solution contained 1% by volume of CH₃(CH₂)₅SH and 99% by volume of toluene as the solvent, as in the solution of Example 3.

### Evaluation 3

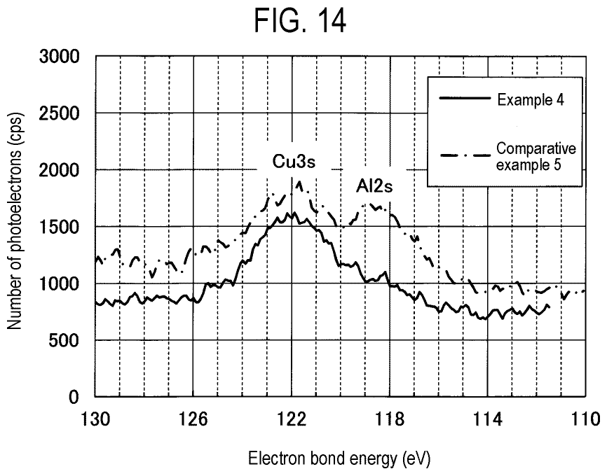

FIG. 13 shows data obtained by measuring the surface states of the first regions A1 immediately after the formation of AlO films with an X-ray photoelectron spectroscopy (XPS) device for Example 3 and Comparative Example 4. As is clear from FIG. 13, according to Example 3, since the relative strength of the Cu peak to the Al peak is higher compared to that of Comparative Example 4, it can be seen that the film formation of the AlO film was inhibited.

From FIG. 13, it can be seen that, even when the first processing liquid 22 is applied to the surface 10a of the substrate 10 through the dip coating method in S21 of FIG. 2, the same tendency as in the case where the vapor of the first processing liquid 22 is supplied to the surface 10a of the substrate 10 is obtained. That is, when the formation of the SAM 20 using a solution and the modification of the SAM 20 using an undiluted solution are executed, it is possible to improve the blocking performance of the SAM 20 compared to the case in which only the formation of the SAM using the solution is executed.

### Example 4 and Comparative Example 5

In Example 4, the formation of a SAM 20 using the first processing liquid 22 and the modification of the SAM 20 using the second processing liquid were executed. As the first processing liquid 22, a solution containing 1% by volume of a thiol compound was used, whereas an undiluted solution containing 100% by volume of a thiol compound was used as the second processing liquid. In Comparative Example 5, only the formation of a SAM using the undiluted solution was executed. The details will be described below.

### Example 4

In Example 4, the substrate 10 was processed in the same manner as in Example 3, except that, alternately supplying TMA gas and water vapor to the surface 10a of the substrate 10 was repeated 80 times at the time of forming an AlO film.

In the dip coating method, the entire substrate 10 was immersed in the first processing liquid 22 at 85 degrees C. for 30 minutes. The first processing liquid 22 was a solution containing 1% by volume of CH₃(CH₂)₅SH and 99% by volume of toluene as the solvent, as in the first processing liquid 22 of Example 3.

The second processing liquid was also an undiluted solution containing 100% by volume of CH₃(CH₂)₅SH, as in the second processing liquid of Example 3. In Example 4, the thiol compound of the second processing liquid and the thiol compound of the first processing liquid were the same.

When the surface 10a of the substrate 10 was observed with a scanning electron microscope (SEM) after S2 and before S3 in FIG. 1, it was confirmed that the SAM was selectively formed in the first region A1. Furthermore, when the surface 10a of the substrate 10 was observed with a scanning electron microscope (SEM) after S3 in FIG. 1, it was confirmed that the AlO film was selectively formed in the second region A2. The thickness of the AlO film was 7 nm.

### Comparative Example 5

In Comparative Example 5, the substrate 10 was processed in the same manner as in Example 4, except that only the formation of the SAM using the undiluted solution was executed instead of executing S21 to S24 in FIG. 2. The formation of the SAM using the undiluted solution was executed under the same conditions as in S24 of Example 4. The undiluted solution contained about 100% by volume of CH₃(CH₂)₅SH as in the undiluted solution of Example 4.

### Evaluation 4

FIG. 14 shows data obtained by measuring the surface states of the first regions A1 immediately after the formation of AlO films with an X-ray photoelectron spectroscopy (XPS) device for Example 4 and Comparative Example 5. As is clear from FIG. 14, according to Example 4, since the relative strength of the Cu peak to the Al peak is higher compared to that of Comparative Example 5, it can be seen that the film formation of the AlO film was inhibited.

From FIG. 14, it can be seen that, even when the first processing liquid 22 is applied to the surface 10a of the substrate 10 through the dip coating method in S21 of FIG. 2, the same tendency as in the case where the vapor of the first processing liquid 22 is supplied to the surface 10a of the substrate 10 is obtained. That is, when the formation of the SAM 20 using a solution and the modification of the SAM 20 using an undiluted solution are executed, it is possible to improve the blocking performance of the SAM 20 compared to the case in which only the formation of the SAM using the undiluted solution is executed.

### Example 5 and Comparative Example 6

In Example 5 and Comparative Example 6, unlike Example 1 and the like, the first processing liquid 22 was applied to the surface 10a of the substrate 10 through the spin coating method in S21 of FIG. 2. In Example 5, the formation of a SAM 20 using the first processing liquid 22 and the modification of the SAM 20 using the second processing liquid were executed. Meanwhile, in Comparative Example 6, only the formation of the SAM 20 using the first processing liquid 22 was executed. The details will be described below.

### Example 5

In Example 5, in S21 of FIG. 2, the substrate 10 was processed in the same manner as in Example 1 except that the first processing liquid 22 was applied to the surface 10 a of the substrate 10 through a spin coating method and, as the first processing liquid 22, a solution containing 1% by volume of CH₃(CH₂)₁₇SH as the first raw material 21 and 99% by volume of toluene as the solvent was prepared.

In the spin coating method, the first processing liquid 22 was dropped onto the center of the surface 10 a as the top surface of the substrate 10, while rotating the substrate 10 at 50 rpm. The temperature of the substrate 10 was 27 degrees C. The first processing liquid 22 was a solution containing 1% by volume of CH₃(CH₂)₁₇SH as the first raw material 21 and 99% by volume of toluene as the solvent, as in the first processing liquid 22 of Example 2.

The second processing liquid was an undiluted solution containing 100% by volume of CH₃(CH₂)₅SH as the second raw material, as in the second processing liquid of Example 1. In Example 5, the thiol compound of the second processing liquid and the thiol compound of the first processing liquid were different from each other.

When the surface 10a of the substrate 10 was observed with a scanning electron microscope (SEM) after S2 and before S3 in FIG. 1, it was confirmed that the SAM was selectively formed in the first region A1. Further, when the surface 10a of the substrate 10 was observed with a scanning electron microscope (SEM) after S3 in FIG. 1, it was confirmed that the AlO film was selectively formed in the second region A2. The thickness of the AlO film was 3 nm.

### Comparative Example 6

In Comparative Example 6, the substrate 10 was processed in the same manner as in Example 5, except that only the formation of a SAM using a solution was executed instead of executing S21 to S24 in FIG. 2. The formation of a SAM using the solution was conducted under the same conditions as in S21 of Example 5. The solution was a solution containing 1% by volume of CH₃(CH₂)₁₇SH as the first raw material 21 and 99% by volume of toluene as the solvent, as in the solution of Example 5.

### Evaluation 5

When the surface 10a of the substrates 10 was observed with a scanning electron microscope (SEM) after the formation of the AlO films, according to Comparative Example 6, the AlO film was observed not only in the second region A2 but also in the first region A1, but according to Example 5, no AlO film was observed in the first region A1.

Accordingly, it can be seen that, even when the first processing liquid 22 is applied to the surface 10a of the substrate 10 through the spin coating method in S21 of FIG. 2, the same tendency as in the case where the vapor of the first processing liquid 22 is supplied to the surface 10a of the substrate 10 is obtained. That is, when the formation of the SAM 20 using a solution and the modification of the SAM 20 using an undiluted solution are executed, it is possible to improve the blocking performance of the SAM 20 compared to the case in which only the formation of the SAM using the solution is executed.

Although the embodiments of the film formation method and the film formation apparatus according to the present disclosure have been described above, the present disclosure is not limited to the above-described embodiments or the like. Various changes, modifications, replacements, additions, deletions, and combinations are possible within the scope of the claims. Of course, these also fall within the technical scope of the present disclosure.

For example, the magnitude relationship between the concentration of the first processing liquid 22 and the concentration of the second processing liquid may be reversed. That is, the concentration of the second processing liquid is higher than the concentration of the first processing liquid 22 in the above embodiment, but may be lower than the concentration of the first processing liquid 22. In the latter case as well, there is a possibility that the blocking performance of the SAM 20 can be improved.

This application claims priority based on Japanese Patent Application No. 2019-239350 filed with the Japan Patent Office on Dec. 27, 2019, and the entire disclosure of Japanese Patent Application No. 2019-239350 is incorporated herein in its entirety by reference.

### EXPLANATION OF REFERENCE NUMERALS

10: substrate, 10a: surface, A1: first region, A2: second region, 20: self-assembled monolayer (SAM), 21: first raw material, 22: first processing liquid, 23: vapor, 30: target film

What is claimed is:

1. A film formation method comprising:
preparing a substrate including, on a surface of the substrate, a first region in which a first material is exposed and a second region in which a second material different from the first material is exposed;
selectively forming a self-assembled monolayer in the first region, among the first region and the second region; and
selectively forming a desired target film in the second region, among the first region and the second region, by using the self-assembled monolayer formed in the first region,
wherein the selectively forming the self-assembled monolayer includes:
selectively forming the self-assembled monolayer in the first region by using a first processing liquid including a first raw material of the self-assembled monolayer and a solvent; and
modifying the self-assembled monolayer formed of the first processing liquid by supplying vapor of a solid of a second raw material of the self-assembled monolayer to the surface of the substrate.

2. The film formation method of claim 1, wherein the selectively forming the self-assembled monolayer in the first region by using the first processing liquid includes supplying vapor of the first processing liquid to the surface of the substrate.

3. The film formation method of claim 2, wherein the selectively forming the self-assembled monolayer in the first region by using the first processing liquid includes:
depositing the first raw material on the surface of the substrate by supplying the first processing liquid; and
removing the first raw material deposited on the surface and unreacted on the surface.

4. The film formation method of claim 1, wherein the selectively forming the self-assembled monolayer in the first region by using the first processing liquid includes applying the first processing liquid to the surface of the substrate through a dip coating method.

5. The film formation method of claim 1, wherein the selectively forming the self-assembled monolayer in the first region by using the first processing liquid includes applying the first processing liquid to the surface of the substrate through a spin coating method.

6. The film formation method of claim 1, wherein the forming the self-assembled monolayer includes exposing the surface of the substrate to an air atmosphere after the forming the self-assembled monolayer by using the first processing liquid and before the modifying the self-assembled monolayer.

7. The film formation method of claim 1, wherein the first material in the first region is a metal or a semiconductor,
wherein the second material in the second region is an insulating material, and
wherein the first raw material and the second raw material of the self-assembled monolayer are thiol compounds.

8. The film formation method of claim 1, wherein the first material in the first region is an insulating material,
wherein the second material in the second region is a metal or a semiconductor, and
wherein the first raw material and the second raw material of the self-assembled monolayer are silane compounds.

9. The film formation method of claim 1, wherein a concentration of the first raw material in the first processing liquid is in a range from 0.1% by volume to 10% by volume.

10. The film formation method of claim 1, further comprising:
after the selectively forming the self-assembled monolayer in the first region, removing the first raw material deposited on the substrate and unreacted on the substrate.

11. The film formation method of claim 10, wherein the removing the first raw material deposited on the substrate and unreacted on the substrate is performed by exposing the substrate to toluene heated to a range of 65 degrees C. to 85 degrees C.

12. The film formation method of claim 10, further comprising:
after the removing the first raw material deposited on the substrate and unreacted on the substrate, exposing the substrate to an air atmosphere.
